(19) United States
(12) Patent Application Publication
(10) Pub. No.: US 2023/0040210 A1
(43) Pub. Date: Feb. 9, 2023

(54) SURFACE TREATMENT AGENT, SURFACE TREATMENT METHOD, AND METHOD FOR REGION-SELECTIVELY PRODUCING FILM ON SUBSTRATE

(71) Applicant: TOKYO OHKA KOGYO CO., LTD., Kawasaki-shi (JP)

(72) Inventors: Kenji SEKI, Kawasaki-shi (JP); Jun IIOKA, Kawasaki-shi (JP)

(21) Appl. No.: 17/811,528

(22) Filed: Jul. 8, 2022

(30) Foreign Application Priority Data
Jul. 26, 2021 (JP) 2021-121790

(51) Int. Cl. C23C 16/02; C07F 9/30; C23C 16/455

(52) U.S. Cl. CPC C23C 16/0272; C07F 9/301; C23C 16/45525

(57) ABSTRACT

A surface treatment agent including a compound represented by the general formula HO—P(═O)R¹R² in which R¹ and R² are each independently bonded to the phosphorus atom and are each independently a hydrogen atom, an alkyl group, a fluorinated alkyl group, or an aromatic hydrocarbon group which may have a substituent, provided that R¹ and R² are not hydrogen atoms at the same time, and an organic solvent.

This application is claims priority to Japanese Patent Application No. 2021-121790, filed Jul. 26, 2021, the entire content of which is incorporated herein by reference.

### BACKGROUND OF THE INVENTION

### Field of the Invention

The present invention relates to a surface treatment agent, a surface treatment method, and a method for region-selectively forming a film on a substrate.

### Related Art

In recent years, trends toward higher integration and miniaturization of semiconductor devices have grown. Accompanied with this, miniaturization of a patterned organic film serving as a mask and an inorganic patterned film prepared by an etching process have advanced. Thus, film thickness control in an atomic layer level has been demanded for organic films or inorganic films formed on semiconductor substrates. As a method for forming a thin film on a substrate in the atomic layer level, an atomic layer deposition (ALD) method (hereinafter, also simply referred to as an “ALD method”) has been known. The ALD method is known to have higher step difference covering properties (step coverage) and film-thickness controllability as compared with a general chemical vapor deposition (CVD) method.

The ALD method is a thin film formation technique in which two types of gases having, as main components, elements of a film to be formed are alternately supplied onto a substrate to form a thin film on the substrate in atomic layer units, and this treatment is repeated a plurality of times to form a film having a desired thickness. The ALD method uses a deposition self-controlling function (self-limiting function), in which, during supply of raw material gases, only enough components of the raw material gases are adsorbed onto a substrate surface to form one or a few atomic layers, while excess raw material gas does not contribute to the deposition. For example, to form an Al₂O₃ film on a substrate, a raw material gas composed of TMA (trimethyl aluminum) and an oxidizing gas including oxygen are used. To form a nitride film on a substrate, a nitriding gas is used instead of the oxidizing gas.

In recent years, a method for region-selectively producing a film on a substrate surface has been attempted by using the ALD method (see Patent Document 1 and Non-Patent Document 1). Due to this, a substrate having a surface modified in a region-selective manner has been demanded, so that the substrate surface can be suitably applied in the method for region-selectively producing a film on the substrate by the ALD method. As a method for obtaining a substrate having such a region-selectively modified surface, a method for surface treating a metal substrate and an insulating substrate, the method selectively rendering the former water repellent, by using, for example, dodecylphosphonic acid or octadecyl phosphonic acid has been disclosed (see Patent Document 2). There is, however, room for improvement in more selectively rendering the metal substrate water-repellent than the insulating substrate.
Patent Document 1: Japanese Unexamined Patent Application (Translation of PCT Application), Publication No. 2003-508897
Patent Document 2: Japanese Unexamined Patent Application, Publication No. 2021-014631
Non-Patent Document 1: J. Phys. Chem. C 2014, 118, 10957-10962

### SUMMARY OF THE INVENTION

The present invention has been made considering the above situation, and it is an object of the present invention to provide a surface treatment agent, capable of surface treating a substrate surface including a metal region and an insulator region that are adjacent to each other, such that water repellency of the insulator region can be suppressed and the metal region can be more selectively rendered water repellent; a method for surface treatment; and a method for region-selectively forming a film on a substrate surface.

The present inventors have found that the above problem can be solved by using a surface treatment agent for treating a substrate surface including two or more regions; the two or more regions including at least one metal region and at least one insulator region; of the two or more regions, the at least one metal region and the at least one insulator region being adjacent to each other; the surface treatment agent including a phosphorus compound (P) having a specific structure, and an organic solvent (S). Based on this finding, the present invention has been completed.

A first aspect of the present invention relates to a surface treatment agent for use in treating a substrate surface.

The surface includes two or more regions,

the two or more regions include at least one metal region and at least one insulator region,

of the two or more regions, the at least one metal region and the at least one insulator region are adjacent to each other, and

the surface treatment agent includes: a compound (P) represented by the following general formula (P-1):

HO—P(═O)R¹R² (P-1)

in which in the formula, R¹ and R² are each independently bonded to the phosphorus atom and are each independently a hydrogen atom, an alkyl group, a fluorinated alkyl group, or an aromatic hydrocarbon group which may have a substituent, provided that R¹ and R² are not hydrogen atoms at the same time, and

an organic solvent (S).

A second aspect of the present invention relates to a surface treatment method for a substrate surface.

The surface includes two or more regions,

the two or more regions include at least one metal region and at least one insulator region, and

of the two or more regions, the at least one metal region and the at least one insulator region are adjacent to each other.

The method includes exposing the surface to the surface treatment agent as described in the first aspect,

such that a water contact angle of the metal region is higher than a water contact angle of the insulator region adjacent to the metal region by 10° or more through the reaction between the compound (P) and the regions.

A third aspect of the present invention relates to a method for region-selectively forming a film on a substrate surface, the method including: subjecting the substrate surface to surface treatment by the surface treatment method as described in the second aspect; and

forming a film on the substrate surface subjected to the surface treatment, by an atomic layer deposition method,

such that a larger amount of material for the film is deposited on the insulator region than on the metal region.

According to the present invention, it is possible to provide a surface treatment agent, capable of surface treating a substrate surface including a metal region and an insulator region that are adjacent to each other, such that water repellency of the insulator region can be suppressed and the metal region can be more selectively rendered water repellent; a method for surface treatment using the surface treatment agent; and a method for region-selectively forming a film on a substrate surface by using the surface treatment method.

### DETAILED DESCRIPTION OF THE INVENTION

### <Surface Treatment Agent>

The surface treatment agent is used for treating a substrate surface. The substrate surface includes two or more regions. The two or more regions include at least one metal region and at least one insulator region. Of the two or more regions, at least one metal region and at least one insulator region are adjacent to each other. Here, being adjacent includes a case in which at least one metal region and at least one insulator region share a boundary line and are adjacent to each other, and a case in which at least one metal region and at least one insulator region are adjacent to each other without sharing a boundary line or are spaced apart. The surface treatment agent contains a compound (P) represented by the following general formula (P-1):

HO—P(═O)R¹R² (P-1)

in which in the formula, R¹ and R² are each independently bonded to the phosphorus atom and are each independently a hydrogen atom, an alkyl group, a fluorinated alkyl group, or an aromatic hydrocarbon group which may have a substituent, provided that R¹ and R² are not hydrogen atoms at the same time, and
an organic solvent (S). By surface treating a substrate surface including a metal region and an insulator region that are adjacent to each other, using the above-mentioned surface treatment agent, water repellency of the insulator region can be suppressed and the metal region can more selectively be rendered water-repellent.

### (Substrate and Substrate Surface)

As the “substrate” that is a target of the surface treatment, a substrate used for producing semiconductor devices can be exemplified. Examples of such a substrate include a silicon (Si) substrate, a silicon nitride (SiN) substrate, a silicone oxide film (SiOx) substrate, a tungsten (W) substrate, a cobalt (Co) substrate, a germanium (Ge) substrate, an aluminum (Al) substrate, a nickel (Ni) substrate, a ruthenium (Ru) substrate, a copper (Cu) substrate, a titanium nitride (TiN) substrate, a tantalum nitride (TaN) substrate, a silicon germanium (Site) substrate, and the like. Examples of the “substrate surface” include, in addition to the substrate surface itself, surfaces of a patterned or unpatterned inorganic layer provided on the substrate. The surface of a patterned inorganic layer should be construed as substantially including a side surface of the pattern as well.

Examples of the patterned inorganic layer provided on the substrate include a patterned inorganic layer formed by producing an etching mask on the surface of an inorganic layer present on the substrate by way of a photoresist method, followed by an etching process; and a patterned inorganic layer formed on the substrate surface by way of the atomic layer deposition (ALD method). Note that, in order to form a patterned inorganic layer on a substrate surface by the ALD method, the surface treatment agent of the present embodiment can be also used. By using the surface treatment agent of the present embodiment, selectivity between a region corresponding to the metal region and a region corresponding to the insulator region, as the inorganic layer, can be secured. Examples of the inorganic layer include, in addition to the substrate itself, an oxide film of an element constituting the substrate; and a film or a layer of inorganic materials formed on the substrate surface, such as silicon nitride (SiN), silicon oxide film (SiOx), tungsten (W), cobalt (Co), germanium (Ge), aluminum (Al), nickel (Ni), ruthenium (Ru), copper (Cu), silver (Ag), titanium (Ti), gold (Au), chromium (Cr), molybdenum (Mo), aluminum oxide (Al₂O₃), titanium oxide (TiO₂), zirconium oxide (ZrO₂), hafnium oxide (HfO₂), tantalum oxide (Ta₂O₅), titanium nitride (TiN), tantalum nitride (TaN), silicon germanium (Site), and silicon oxide (SiO₂). Such a film or layer is not particularly limited, and examples thereof include a film or a layer of an inorganic material formed in a manufacturing process of a semiconductor device. As the unpatterned inorganic layer provided on the substrate, a film or a layer of an inorganic material composed of the same materials as those for the patterned inorganic layer provided on the substrate can be exemplified.

### (Pretreatment of Substrate Surface)

The substrate surface is preferably pretreated. A treatment agent (hereinafter, sometimes referred to as “pretreatment agent”) for pretreating a substrate surface is not particularly limited as long as it can remove a natural oxide film present on the substrate surface and impart a hydroxy group to the substrate surface. Imparting a hydroxy group in advance improves water repellency of the substrate surface after treatment with the surface treatment agent according to the present invention. Specific examples of the pretreatment agent include peroxides such as hydrogen peroxide, perhalogenic acids such as periodic acid, oxo acids such as nitric acid and hypochlorous acid, phosphoric acid, citric acid, acetic acid, hydrofluoric acid (HF), and the like. The pretreatment agent may be appropriately selected depending on the type of substrates to be used, and for example, in a case of a substrate containing W or Ru, at least one type selected from the group consisting of hydrogen peroxide and perhalogenic acids is preferred. Further, the at least one type selected from the group consisting of hydrogen peroxide and perhalogenic acids is also preferred in a case in which an inorganic substance such as SiO₂ or Al₂O₃ is present on the substrate surface, from the viewpoint of being able to treat the metal surface without damaging the inorganic substance present on the substrate surface. On the other hand, in a case of a substrate containing Cu, an aqueous HF solution, acetic acid, citric acid, phosphoric acid, or nitric acid is preferably used as the pretreatment agent from the viewpoint of natural oxide film removability and improvement in hydrophilicity of the substrate surface. The pretreatment agent may be used alone, or two or more types thereof may be used.

### (Metal Region and Insulator Region)

The metal region includes a metal or a conductive metal-containing compound. The metal region may be defined as a conductor region, contrary to the insulator region described below. As the metal or conductive metal-containing compound, copper (Cu), cobalt (Co), aluminum (Al), silver (Ag), nickel (Ni), titanium (Ti), gold (Au), chromium (Cr), molybdenum (Mo), tungsten (W), ruthenium (Ru), titanium nitride (TiN), tantalum nitride (TaN), and the like are preferred among the above-mentioned inorganic substances. The insulator region is composed of one or more insulating compounds selected from the group consisting of oxides, nitrides, carbides, carbonitrides, oxynitrides, oxycarbonitrides, and insulating resins, and oxides, nitrides, carbides, carbonitrides, oxynitrides or oxycarbonitrides are preferred. The oxides are preferably aluminum oxide (Al₂O₃), titanium oxide (TiO₂), zirconium oxide (ZrO₂), hafnium oxide (HfO₂), tantalum oxide (Ta₂O₅), silicon oxide (SiOx (1≤X≤2)), fluorine-containing silicon oxide (SiOF), and carbon-containing silicon oxide (SiOC). Preferable examples of the nitrides include silicon nitride (SiN) and boron nitride (BN). Preferable examples of the carbides include silicon carbide (SiC). Preferable examples of the carbonitrides include silicon carbonitride (SiCN). Preferable examples of the oxynitrides include silicon oxynitride (SiON). Preferable examples of the oxycarbonitrides include silicon oxycarbonitride (SiOCN). Preferable examples of the insulating resins include polyimides, polyesters, and plastic resins.

(Embodiment of Substrate Surface consisting of Two Regions)

As an embodiment of the substrate surface consisting of two regions, an embodiment in which a region of the two regions is a metal region serving as the first region, and a region adjacent thereto is an insulator region serving as the second region can be mentioned. Here, the first region and the second region may or may not be respectively divided into a plurality of regions. Examples of the first region and the second region include: an embodiment in which the substrate surface itself is a metal region serving as the first region and a layer composed of an insulator formed on the substrate surface is an insulator region serving as the second region; an embodiment in which the substrate surface itself is an insulator region serving as the first region and a layer being composed of a metal and being formed on the substrate surface is a metal region serving as the second region; an embodiment in which a layer being composed of a metal and being formed on the substrate surface is a metal region serving as the first region and a layer being composed of an insulator and being formed on the substrate surface is an insulator region serving as the second region; and an embodiment in which a portion of the substrate surface that is an insulator is a metal region serving as the first region and a layer being composed of an insulator and being formed on at least a portion of the substrate surface other than the metal region and/or at least a portion of the substrate surface other than the metal region (or an entirety of the substrate surface other than the metal region) is an insulator region serving as the second region.

### (Embodiments of Substrate Surface Including Three or More Regions)

Examples of the embodiments of substrate surfaces each including three or more regions include: an embodiment in which one region of the two or more regions is a metal region serving as the first region, a region adjacent thereto is an insulator region serving as the second region, and a region adjacent to the second insulator region is a metal region serving as the third region; an embodiment in which one region of the two or more regions is an insulator region serving as the first region, a region adjacent thereto is a metal region serving as the second region, and a region adjacent to the second metal region is an insulator region serving as the third region; and an embodiment in which one region of the two or more regions is a metal region serving as the first region, a region adjacent thereto is a metal region serving as the second region, and a region adjacent to the second metal region is further an insulator region serving as the third region. Here, the first region and the third region differ from each other in materials. The first region, the second region, and the third region may or may not be respectively divided into a plurality of regions. Examples of the first region, the second region and the third region include an embodiment in which the substrate surface itself is a metal region serving as the first region, a surface of an insulator region being adjacent to the substrate and being formed on the substrate surface is the second region, and a surface of a metal region being adjacent to the second region and being formed on the substrate surface is the third region; and an embodiment in which the substrate surface itself is an insulator region serving as the first region, a surface of a metal region being adjacent to the substrate and being formed on the substrate surface is the second region, and a surface of an insulator region being adjacent to the second region and being formed on the substrate surface is the third region. The same way of thinking can be applied to the case where four or more regions are present. The upper limit value of the number of regions, which differ in material, is not particularly limited as long as the effect of the present invention is not impaired, but is, for example, 7 or less or 6 or less, and is typically 5 or less.

### (Compound (P))

Compound (P) is a phosphinic acid derivative. Compound (P) is hydrophilic at the moiety [HO—P(═O)—] and hydrophobic at the moieties [—R′] and [—R²]. It is thus presumed that, with respect to the substrate surface including the metal region and the insulator region that are adjacent to each other, the moiety [HO—P(═O)—] functions as a group that adsorbs to the metal region, whereas the moieties [—R′] and [—R²] function as water-repellent groups. The compound (P) therefore functions as a material (SAM agent) that forms a self-assembled monolayer.

In the compound (P) represented by the formula (P-1), at least one selected from the alkyl group as R¹ and R² is preferably a linear or branched alkyl group having 8 or more carbon atoms. The upper limit of the number of carbon atoms of the alkyl group as R¹ and R² is not particularly limited, but is typically 50 or less, and may be 30 or less.

Preferable examples of the alkyl group as R¹ and R² include methyl, ethyl, n-propyl, n-butyl, n-pentyl, n-hexyl, n-heptyl, n-octyl, n-nonyl, n-decyl, n-undecyl, n-dodecyl, n-tridecyl, n-tetradecyl, n-pentadecyl, n-hexadecyl, n-heptadecyl, n-octadecyl, n-nonadecyl, n-icosyl, n-henicosyl, and n-docosyl groups, as well as alkyl groups that are in a relationship of structural isomers with these alkyl groups. The at least one alkyl group selected from the alkyl group as R¹ and R² is preferably a n-octyl, n-nonyl, n-decyl, n-undecyl, n-dodecyl, n-tridecyl, n-tetradecyl, n-pentadecyl, n-hexadecyl, n-heptadecyl, n-octadecyl, n-nonadecyl, n-icosyl, n-henicosyl, or n-docosyl group, as well as an alkyl group that is in a relationship of structural isomers with these alkyl groups.

In the compound (P) represented by the formula (P-1), the fluorinated alkyl group of R¹ and R² is preferably a linear or branched fluorinated alkyl group having 8 or more carbon atoms.

Preferred examples of the fluorinated alkyl group as R¹ and R² include a group having some or all of the hydrogen atoms of the alkyl group of R¹ and R² substituted with fluorine atoms.

In the compound (P) represented by the formula (P-1), examples of the aromatic hydrocarbon group which may have a substituent, of R¹ and R², includes phenyl, naphthyl, anthryl, p-methylphenyl, p-tert-butylphenyl, p-adamantylphenyl, tolyl, xylyl, cumenyl, mesityl, biphenyl, phenanthryl, 2,6-diethylphenyl, and 2-methyl-6-ethylphenyl groups.

Among them, it is preferable that among R¹ and R², one is a hydrogen atom and the other is a linear or branched alkyl group having 8 or more carbon atoms. As the linear or branched alkyl group having 8 or more carbon atoms, an octadecyl group, a docosyl group, and a triacontyl group are more preferred.

The compound (P) may be used alone, and two or more types thereof may be used.

The content of the compound (P) is preferably 0.001% by mass or more and 5% by mass or less, more preferably 0.005% by mass or more and 4% by mass or less, more preferably 0.01% by mass or more and 3% by mass or less, and most preferably 0.03% by mass or more and 3% by mass or less, based on the total mass of the surface treatment agent, from the viewpoint of suppressing water repellency of the insulator region and more selectively rendering the metal region water repellent.

### (Organic Solvent (S))

The organic solvent (S) has a function of improving water repellency of the metal region by the compound (P). Examples of the organic solvent (S) include: sulfoxides, sulfones, amides, lactams, imidazolidinones, dialkyl glycol ethers, monoalcohol-based solvents, (poly)alkylene glycol monoalkyl ethers, (poly)alkylene glycol monoalkyl ether acetates, other ethers, ketones, other esters, lactones, linear, branched, or cyclic aliphatic hydrocarbons, aromatic hydrocarbons, terpenes, and the like.

Examples of the sulfoxides include dimethyl sulfoxide.

Examples of the sulfones include: dimethylsulfone, diethylsulfone, bis(2-hydroxyethyl)sulfone, and tetramethylene sulfone.

Examples of the amides include: N,N-dimethylformamide, N-methylformamide, N,N-dimethylacetamide, N-methylacetamide, and N,N-diethylacetamide.

Examples of the lactams include: N-methyl-2-pyrrolidone, N-ethyl-2-pyrrolidone, N-propyl-2-pyrrolidone, N-hydroxymethyl-2-pyrrolidone, and N-hydroxyethyl-2-pyrrolidone.

Examples of the imidazolidinones include: 1,3-dimethyl-2-imidazolidinone, 1,3-diethyl-2-imidazolidinone, and 1,3-diisopropyl-2-imidazolidinone.

Examples of the dialkyl glycol ethers include: dimethyl glycol, dimethyl diglycol, dimethyl triglycol, methyl ethyl diglycol, diethyl glycol, and triethylene glycol butyl methyl ether.

Examples of the monoalcohol-based solvents include: methanol, ethanol, n-propanol, isopropanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethyl-1-butanol, sec-heptanol, 3-heptanol, 1-octanol, 2-ethylhexanol, sec-octanol, n-nonyl alcohol, 2,6-dimethyl-4-heptanol, n-decanol, sec-undecyl alcohol, trimethylnonyl alcohol, sec-tetradecyl alcohol, sec-heptadecyl alcohol, methyl isobutyl carbinol, phenol, cyclohexanol, methylcyclohexanol, 3,3,5-trimethylcyclohexanol, benzyl alcohol, phenylmethylcarbinol, diacetone alcohol, and cresol.

As the (poly)alkylene glycol monoalkyl ethers, for example, the following can be mentioned: ethylene glycol monomethyl ether, ethylene glycol monoethyl ether, ethylene glycol mono-n-propyl ether, ethylene glycol mono-n-butyl ether, diethylene glycol monomethyl ether, diethylene glycol monoethyl ether, diethylene glycol mono-n-propyl ether, diethylene glycol mono-n-butyl ether, triethylene glycol monomethyl ether, triethylene glycol monoethyl ether, propylene glycol monomethyl ether, propylene glycol monoethyl ether, propylene glycol mono-n-propyl ether, propylene glycol mono-n-butyl ether, dipropylene glycol monomethyl ether, dipropylene glycol monoethyl ether, dipropylene glycol mono-n-propyl ether, dipropylene glycol mono-n-butyl ether, tripropylene glycol monomethyl ether, and tripropylene glycol monoethyl ether.

Examples of the (poly)alkylene glycol monoalkyl ether acetates include: ethylene glycol monomethyl ether acetate, ethylene glycol monoethyl ether acetate, ethylene glycol monobutyl ether acetate, diethylene glycol monomethyl ether acetate, diethylene glycol monoethyl ether acetate, propylene glycol monomethyl ether acetate, propylene glycol monoethyl ether acetate.

Examples of the other ethers include: dimethyl ether, diethyl ether, methyl ethyl ether, dipropyl ether, diisopropyl ether, dibutyl ether, diisoamyl ether, diethylene glycol dimethyl ether, diethylene glycol methylethyl ether, diethylene glycol monobutyl ether, diethylene glycol diethyl ether, tetraethylene glycol dimethyl ether, and tetrahydrofuran.

Examples of the ketones include: methyl ethyl ketone, cyclohexanone, 2-heptanone, 3-heptanone, and 2,6-dimethyl-4-heptanone.

Examples of the other esters may include: alkyl lactates, such as methyl lactate and ethyl lactate; ethyl 2-hydroxy-2-methylpropionate, methyl 3-methoxypropionate, ethyl 3-methoxypropionate, methyl 3-ethoxy propionate, ethyl 3-ethoxy propionate, ethyl ethoxyacetate, ethyl hydroxyacetate, methyl 2-hydroxy-3-methylbutanoate, 3-methoxybutyl acetate, 3-methyl-3-methoxy-1-butyl acetate, 3-methyl-3-methoxybutyl propionate, ethyl acetate, n-propyl acetate, isopropyl acetate, n-butyl acetate, isobutyl acetate, n-pentyl acetate, n-hexyl acetate, n-heptyl acetate, n-octyl acetate, n-pentyl formate, isopentyl acetate, n-butyl propionate, ethyl butyrate, n-propyl butyrate, isopropyl butyrate, butyl butyrate, methyl n-octanoate, methyl decanoate, methyl pyruvate, ethyl pyruvate, n-propyl pyruvate, methyl acetoacetate, ethyl acetoacetate, ethyl 2-oxobutanoate, dimethyl adipate, and propylene glycol diacetate.

Examples of the lactones include: propylolactone, γ-butyrolactone, and 6-pentyrolactone.

Examples of the linear, branched, or cyclic aliphatic hydrocarbons include: n-hexane, n-heptane, n-octane, n-nonane, methyl octane, n-decane, n-undecane, n-dodecane, 2,2,4,6,6-pentamethylheptane, 2,2,4,4,6,8,8-heptamethylnonane, cyclohexane, and methylcyclohexane.

Examples of the aromatic hydrocarbons include: benzene, toluene, benzotrifluoride, xylene, 1,3,5-trimethylbenzene, naphthalene, and decahydronaphthalene.

Examples of the terpenes include: p-menthane, diphenylmenthane, limonene, terpinene, bornane, norbornane, and pinane.

The organic solvent (S) has a relative dielectric constant of preferably 35 or less, more preferably 20 or less, from the viewpoint of more selectively rendering the metal region water repellent. As the organic solvent (S) having such a low relative dielectric constant, for example, the following can be mentioned: methanol (relative dielectric constant: 33), diethylene glycol monobutyl ether (BDG) (relative dielectric constant: 13.70), propylene glycol monomethyl ether (PE) (relative dielectric constant: 12.71), benzyl alcohol (relative dielectric constant: 13.70), 2-heptanone (relative dielectric constant: 11.74), ethylene glycol monobutyl ether acetate (relative dielectric constant: 8.66), tert-butanol (relative dielectric constant: 12.5), 1-octanol (relative dielectric constant: 10.21), isobutanol (relative dielectric constant: 18.22), benzotrifluoride (relative dielectric constant: 9.18), decahydronaphthalene (relative dielectric constant: 2.16), cyclohexane (relative dielectric constant: 1.99), decane (relative dielectric constant: less than 1), ethyl lactate (EL) (relative dielectric constant: 13.22), diethylene glycol monomethyl ether (relative dielectric constant: 15.76), 1-nonanol (relative dielectric constant: 9.13), toluene (relative dielectric constant: 2.37), propylene glycol monomethyl ether acetate (PM) (relative dielectric constant: 9.4), methyl isobutyl carbinol (MIBC) (relative dielectric constant: 10.47), 2,6-dimethyl-4-heptanol (relative dielectric constant: 2.98), 2-ethyl-1-butanol (relative dielectric constant: 12.6), 2-butanoneoxime (relative dielectric constant: 2.9), n-dibutyl ether (relative dielectric constant: 3.33), butyl butyrate (relative dielectric constant: 4.55), and 2,6-dimethyl-4-heptanone (relative dielectric constant: 9.82).

The organic solvent (S) may be used singly, and two or more types thereof may be used.

### (Other Components)

The other components which may be blended into the surface treatment agent may be used within a range that can improve or does not hinder the effect of suppressing water repellency of the insulator region of the substrate surface containing a metal region and an insulator region that are adjacent to each other, and the effect of more selectively rendering the metal region water repellent. Examples thereof include an acid other than the compound (P), a basic nitrogen-containing compound, a pH adjusting agent, an antioxidant, an ultraviolet ray absorber, a viscosity modifier, and a defoaming agent.

(Acid Other than Compound (P))

As the acid, any one selected from organic acids and inorganic acids may be used as long as it is other than the compound (P).

As the organic acids, the following can be mentioned: carboxylic acids such as formic acid, acetic acid, citric acid, oxalic acid, 2-nitrophenylacetic acid, 2-ethyl hexanoic acid, dodecanoic acid, and 2-hydroxy-1,2,3-propanetricarboxylic acid; saccharic acids such as ascorbic acid, tartaric acid, and glucuronic acid; and sulfonic acids such as benzenesulfonic acid and p-toluenesulfonic acid. Examples of the inorganic acids include hydrofluoric acid (HF), phosphonic acid (HP(═O) (OH)₂), phosphoric acid (H₃PO₄), hydrochloric acid, nitric acid, and boric acid. Among them, a carboxylic acid or an inorganic acid is preferred as the acid. Acetic acid, 2-hydroxy-1,2,3-propanetricarboxylic acid, phosphonic acid (HP(═O) (OH)₂) or hydrofluoric acid (HF) is more preferred, phosphonic acid (HP(═O) (OH)₂) or hydrofluoric acid (HF) is more preferred, and hydrofluoric acid is most preferred.

### (Basic Nitrogen-Containing Compounds)

The basic nitrogen-containing compound refers to a compound that suppresses the function of the compound (P) to render the insulator region water repellent. Although such properties of the basic nitrogen-containing compound are not clear, it is presumed that the cationic species of the basic nitrogen-containing compound adsorb on the insulator region and this inhibits the compound (P) from adsorbing on the insulator region. The basic nitrogen-containing compound is not particularly limited as long as it has such a property, and examples thereof include a quaternary ammonium compound, a pyridinium halide, a pyrrolidinium halide, a bipyridinium halide, or an amine or a salt thereof having a pK_{b} of 2.5 or less (hereinafter, also referred to as “low pK_{b} amine”).

Examples of the quaternary ammonium compound include a quaternary ammonium salt represented by the following formula (b1).

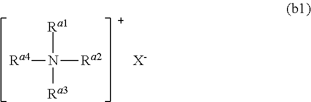

In the formula (b1), R^{a1} to R^{a4} each independently represents an alkyl group having 1 to 16 carbon atoms, an aryl group having 6 to 16 carbon atoms, an aralkyl group having 7 to 16 carbon atoms, or a hydroxyalkyl group having 1 to 16 carbon atoms. At least two selected from R^{a1} to R^{a4} may be bonded to each other to form a cyclic structure, and in particular, at least one selected from the combination of R^{a1} and R^{a2} and the combination of R^{a3} and R^{a4} may be bonded to each other to form a cyclic structure. In the formula (b1), X⁻ represents a hydroxide ion, a chloride ion, a fluoride ion, or an organic carboxylic acid ion which may have fluorine. Examples of the organic carboxylic acid ion which may have fluorine include acetate ions and trifluoroacetate ions.

Among the compounds represented by the formula (b1), hydroxides, chlorides, or fluorides of the following are preferred from the viewpoint of availability: tetramethylammonium, tetraethylammonium, tetrapropylammonium, tetrabutylammonium, methyltripropylammonium, methyltributylammonium, ethyltrimethylammonium, dimethyldiethylammonium salt, benzyltrimethylammonium, hexadecyltrimethylammonium, (2-hydroxyethyl) trimethylammonium, and spiro-(1,1′)-bipyrrolidinium. From the viewpoint of the effect of the present invention, hydroxides or fluorides are more preferred, and hydroxides or fluorides of tetramethylammonium and benzyltrimethylammonium are more preferred. Examples of the pyridinium halides include chlorides or fluorides of pyridinium, and fluorides are preferred. Examples of the pyrrolidinium halides include chlorides or fluorides of pyrrolidinium, and fluorides are preferred. Examples of the bipyridinium halides include chlorides or fluorides of bipyridinium may be mentioned and fluorides are preferred.

The low pK_{b} amine preferably has a pK_{b} of 2.0 or less, and more preferably 1.5 or less. Examples of the low pK_{b} amine include guanidine derivatives. Note that the pK_{b} is a value measured at 25° C.

Examples of the guanidine derivatives include methylguanidine, dimethylguanidine, trimethylguanidine, tetramethylguanidine or a chloride salt or a fluoride salt thereof. Among these, tetramethylguanidine or a fluoride salt thereof is preferred.

The surface treatment agent is obtained by mixing, by a known method, the aforementioned compound (P), the organic solvent (S), and other components, as required.

### <Surface Treatment Method>

Next, the surface treatment method using the aforementioned surface treatment agent will be described. The surface treatment method is a surface treatment method for a substrate surface. The substrate surface includes two or more regions. The two or more regions include at least one metal region and at least one insulator region. Of the two or more regions, the at least one metal region and the at least one insulator region are adjacent to each other. Here, being adjacent includes a case in which at least one metal region and at least one insulator region share a boundary line and are adjacent to each other, or a case in which at least one metal region and at least one insulator region are adjacent to each other without sharing a boundary line or are spaced apart. The surface treatment method includes exposing the surface to the surface treatment agent described above. In the surface treatment method, the reaction between the compound (P) and the regions makes a water contact angle of the metal region higher by 10° or more than a water contact angle of the insulator region adjacent to the metal region.

The substrate and the substrate surface to be subjected to the surface treatment method, the metal and insulator regions, and the surface treatment agent to be used in the surface treatment method are the same as the substrate and the substrate surface, the metal and insulator regions, and the surface treatment agent in the “Surface Treatment Agent” described above.

In the surface treatment method, the water contact angle of the metal region is made higher by 10° or more than the water contact angle of the insulator region adjacent to the metal region. This indicates that the metal region is made water-repellent and the water repellency of the insulator region is suppressed.

### (Exposure)

As a method of exposing the substrate surface to the surface treatment agent, a method of exposure by applying (e.g., coating) the surface treatment agent to the substrate surface by means of, for example, a dipping method or a spin coating method, a roll coating method, and a doctor blade method can be mentioned.

An exposure temperature is 10° C. or more and 90° C. or less, preferably 20° C. or more and 80° C. or less, more preferably 20° C. or more and 70° C. or less, and most preferably 20° C. or more and 30° C. or less. Exposure time period is preferably 20 seconds or more, more preferably 30 seconds or more, and most preferably 45 seconds or more, from the viewpoint of rendering the metal region water repellent and suppressing water repellency of the insulator region. The upper limit value of the exposure time period is not particularly limited, but is, for example, 2 hours or less, typically 1 hour or less, preferably 15 minutes or less, more preferably 5 minutes or less, and most preferably 2 minutes or less. Cleaning and/or drying may be performed as necessary after the exposure. The cleaning is performed, for example, by water rinsing, active agent rinsing, or the like. Drying is carried out by nitrogen blowing or the like.

Among the adjacent metal region and the insulator region, the exposure allows the compound (P) to selectively adsorb on the metal region. As a result, the water contact angle of the metal region can be made higher by 10° or more, preferably 15° or more, more preferably 20° or more, and most preferably 25° or more than the water contact angle of the insulator region adjacent to the metal region. The water contact angle of the substrate surface after exposure to the surface treatment agent can be, for example, 50° or more and 140° or less. By controlling the material of the substrate surface, the type and amount of the surface treatment agent to be used, the exposure conditions and the like, the water contact angle can be set to 50° or more, preferably 60° or more, more preferably 70° or more, and most preferably 90° or more. The upper limit value of the contact angle is not particularly limited, but is, for example, 140° or less, and typically 130° or less. More specifically, the water contact angle of the metal region is preferably 70° or more, more preferably 80° or more, more preferably 90° or more, and most preferably 100° or more. The upper limit value of the contact angle is not particularly limited, but is, for example, 140° or less. The water contact angle of the insulator region is preferably 70° or less, more preferably 65° or less, and most preferably 60° or less. The lower limit value of the contact angle is not particularly limited, but is, for example, 50° or more.

### <Method for Region-Selectively Forming Film on Substrate Surface>

Next, a method for region-selectively forming a film on a substrate surface using the above-described surface treatment method will be described. The method for region-selectively forming a film on a substrate surface includes: treating the substrate surface by the surface treatment method, and forming a film on the surface-treated substrate by an atomic layer deposition method (ALD method), such that a larger amount of the film material is deposited on the insulator region than on the metal region.

As a result of the surface treatment, the water contact angle of the metal region can be made higher by 10° or more than the water contact angle of the insulator region adjacent to the metal region. On the metal region having a higher water contact angle than the insulator region, a film forming material does not easily adsorb in the ALD method. As a result, by repeating an ALD cycle, it is possible to selectively increase film thickness on the insulator region.

### (Film Formation by ALD Method)

Although the film forming method by the ALD method is not particularly limited, the film forming method performed by adsorption using at least two gas phase reactants (hereinafter, simply referred to as “precursor gas”) is preferred. Adsorption using a precursor gas is preferably chemical adsorption. Specifically, examples thereof include a method including the following steps (a) and (b) and repeating the steps (a) and (b) at least 1 time (1 cycle) until a desired film thickness is obtained:

(a) exposing the substrate which was surface-treated by the method as described in the second aspect, to a pulse of a first precursor gas and
(b) after the step (a), exposing the substrate to a pulse of a second precursor gas.

After the step (a) and before the step (b), the method may or may not include a plasma treatment step or a step of removing (purging) the first precursor gas and the reactant thereof by a carrier gas, a second precursor gas, or the like. After the step (b), the method may or may not include a plasma treatment step or a step of removing or purging the second precursor gas and the reactant thereof by a carrier gas or the like. Examples of the carrier gas include an inert gas such as nitrogen gas, argon gas, and helium gas.

Each pulse in each cycle and each layer formed are preferably self-controlled, and more preferably each layer formed is a single atomic layer. The monoatomic layer may have a film thickness of 5 nm or less, preferably 3 nm or less, more preferably 1 nm or less, and most preferably 0.5 nm or less.

Examples of the first precursor gas include: an organometal, a metal halide, and a metal oxide halide, and specifically, examples thereof include: tantalum pentaethoxide, tetrakis(dimethylamino)titanium, pentakis(dimethylamino)tantalum, tetrakis(dimethylamino)zirconium, tetrakis(dimethylamino)hafnium, tetrakis(dimethylamino)silane, copper hexafluoroacetylacetonate vinyltrimethylsilane, Zn(C₂H₆)₂, Zn(CH₃)₂, TMA (trimethylaluminum), TaCl₆, WF₆, WOCl₄, CuCl, ZrCl₄, AlCl₃, TiCl₄, SiCl₄, and HfCl₄.

Examples of the second precursor gas include a precursor gas capable of decomposing the first precursor or a precursor gas capable of removing the ligand of the first precursor, and examples thereof include: H₂O, H₂O₂, O₂, O₃, NH₃, H₂S, H₂Se, PH₃, AsH₃, C₂H₄, and Si₂H₆.

The exposure temperature in the step (a) is not particularly limited, but is, for example, 25° C. or more and 800° C. or less, preferably 50° C. or more and 650° C. or less, more preferably 100° C. or more and 500° C. or less, and most preferably 150° C. or more and 375° C. or less.

The exposure temperature in the step (b) is not particularly limited, and examples thereof include a temperature substantially equal to or higher than the exposure temperature in the step (a). The film formed by ALD method is not particularly limited, but includes: a film containing a pure element (e.g., Si, Cu, Ta, and W), a film containing an oxide (e.g., SiO₂, GeO₂, HfO₂, ZrO₂, Ta₂O₅, TiO₂, Al₂O₃, ZnO, SnO₂, Sb₂O₅, B₂O₃, In₂O₃, and WO₃), a film containing a nitride (e.g., Si₃N₄, TiN, AlN, BN, GaN, and NbN), a film containing a carbide (e.g., SiC), a film containing a sulfide (e.g., CdS, ZnS, MnS, WS₂, and PbS), a film including a selenide (e.g., CdSe and ZnSe), a film containing a phosphide (GaP and InP), a film containing an arsenide (e.g., GaAs and InAs), or a mixture thereof.

### EXAMPLES

Hereinafter, the present invention will be described more specifically based on the Examples and the Comparative Examples, but the present invention is not limited to the following Examples.

### Example 1 and Comparative Example 1

### (Preparation of Surface Treatment Agent)

With the following organic solvent (S), each of the following compounds (P) was uniformly mixed in a content described in Table 1 below and surface treatment agents of Example 1 and Comparative Example 1 were prepared. As compounds (P), the following P1 and P2 were used. P1: octadecylphosphinic acid

P2: octadecylphosphonic acid
As the organic solvent (S), the following S1 was used. S1: isobutanol

### (Pretreatment, Surface Treatment)

Using the surface treatment agents of Example 1 and Comparative Example 1 obtained, a Cu substrate, a W substrate, a TaN substrate, and a SiO₂ substrate were surface treated, according to the following method. Specifically, the pretreatment was performed by immersing each substrate in a 25 ppm aqueous HF solution for 1 minute at 25° C. After the pretreatment, each substrate was washed with deionized water for 1 minute. Each substrate after washing with water was dried by a stream of nitrogen. Each substrate after drying was immersed in each of the surface treatment agents described above for 1 minute at 25° C., to perform surface treatment of each substrate. Each substrate after the surface treatment was washed with isopropanol for 1 minute, and then washed with deionized water for 1 minute. Each of the washed substrates was dried by a stream of nitrogen to obtain the surface-treated substrates.

### (Measurement of Water Contact Angle)

The water contact angles of the substrates after the surface treatment and the substrates subjected only to the pretreatment were measured. The water contact angle was measured by dropping droplets (2.0 μL) of pure water on the surface of each substrate, using a Dropmaster 700 (manufactured by Kyowa Interface Science Co., Ltd.), and measuring the contact angle as a contact angle at 2 seconds after dropping. The results are given in Table 1.

TABLE 1

| | | | Water contact angle on | | | |
|---|---|---|---|---|---|---|
| | Compound(P) | Solvent(S) | substrate (°) | | | |
| | Type/mass % | Type/mass % | Cu | W | TaN | SiO₂ |
| Example 1 | P1/0.1 | S1/99.9 | 108 | 57 | 69 | 7 |
| Comparative | P2/0.1 | S1/99.9 | 102 | 44 | 58 | 5 |
| Example 1 | | | | | | |
| Reference | — | — | 12 | 26 | 44 | 6 |
| Comparative | | | | | | |
| Example 1 | | | | | | |

“Reference Comparative Example 1” in Table 1 refers to a test example in which, of the pretreatment and the surface treatment, only the pretreatment was performed. From Table 1, it is seen that in a case in which the surface treatment was performed with the surface treatment agent of Example 1, the water contact angles on the Cu substrate, the W substrate, and the TaN substrate which are metal substrates increased as compared with a case in which the surface treatment was performed with the surface treatment agent of Comparative Example 1. From these experimental results, it can be seen that octadecylphosphinic acid used in Example 1 can more strongly render these metal substrates water repellent compared to octadecylphosphonic acid used in Comparative Example 1. On the other hand, between Example 1 and Comparative Example 1, the water contact angles on SiO₂ substrates, which are insulator substrates, were approximately the same. Further, even between cases in which the surface treatment was performed with the surface treatment agents of Example 1 and the Reference Comparative Example 1, the water contact angles on SiO₂ substrates were approximately the same. From these experimental results, it can be seen that the octadecylphosphinic acid used in Example 1 does not render the insulator substrate water repellent. Summarizing the experimental results above, it can be said that octadecylphosphinic acid can more selectively render the metal substrate water repellent than octadecylphosphonic acid.

(ALD Film Formation Test of Al₂O₃ on Cu Substrate)

Using the surface treatment agents of Example 1 and Comparative Example 1, the surface treatment of Cu substrates and an ALD film formation test of Al₂O₃ were performed according to the following procedures.

### (Procedures)

1. Pretreatment was carried out by immersing the Cu substrate in a 25 ppm aqueous HF solution for 1 minute at 25° C.
2. The Cu substrate after the pretreatment was washed with deionized water for 1 minute. The Cu substrate after washing with water was dried by a stream of nitrogen.
3. The Cu substrate after drying was immersed in a surface treatment agent for 1 minute, followed by stirring and washing with isopropanol for 1 minute, rinsing with deionized water, and then nitrogen blowing.
4. ALD cycle process was performed 91 times under the following conditions:
Atomic Layer Deposition (ALD) Equipment: AT-410 (manufactured by Anric Technologies)
Chamber temperature: 150° C.
Precursor: trimethylaluminum and H₂O

After performing the ALD cycle process 0, 45, or 91 times, a film thickness of Al₂O₃ on each of the Cu substrates was measured by fluorescent X-ray analysis.

A test example in which the substrate was subjected only to the procedure 4 of the procedures 1 to 4, without performing the procedures 1 to 3, was determined as “Reference Comparative Example 2”, and the film thickness of Al₂O₃ was measured in the same manner as described above. Then, ALD-inhibiting ratio was calculated according to the following equation, based on the film thickness of Al₂O₃ obtained by the surface treatment with each of the surface treatment agents of Example 1 and Comparative Example 1, and the film thickness of Al₂O₃ obtained in Reference Comparative Example 2. The results are shown in Table 2.

ALD inhibiting ratio (%)=[1−(Al₂O₃ film thickness surface treated with a surface treatment agent)/(Al₂O₃ film thickness of Reference Comparative Example 2)]×100.

TABLE 2

| | | | | Al₂O₃ film | |
|---|---|---|---|---|---|
| | Compound | Solvent | Number | thickness | ALD |
| | (P) | (S) | of | on Cu | inhibiting |
| | Type/ | Type/ | ALD | substrate | ratio |
| | mass % | mass % | cycles | (nm) | (%) |
| Example 1 | P1/0.1 | S1/99.9 | 0 | 0.0 | — |
| | | | 45 | 0.4 | 91.7 |
| | | | 91 | 0.7 | 92.7 |
| Comparative | P2/0.1 | S1/99.9 | 0 | 0.0 | — |
| Example 1 | | | 45 | 0.6 | 88.8 |
| | | | 91 | 2.6 | 74.0 |
| Reference | — | — | 0 | 0.0 | — |
| Comparative | | | 45 | 5.0 | — |
| Example 2 | | | 91 | 9.9 | — |

It can be seen from the results of Reference Comparative Example 2 that in a case in which ALD film formation was performed without surface treating the Cu substrate with a surface treatment agent, the film thickness of Al₂O₃ reached about 10 nm after 91 cycles. In the surface treatment of the Cu substrate with the surface treatment agent of Comparative Example 1, after 91 cycles, the film thickness of Al₂O₃ decreased, but remained at 2.6 nm, and the ALD-inhibiting ratio also remained at 74.0%. On the other hand, in the surface treatment with the surface treatment agent of Example 1, the film thickness of Al₂O₃ significantly decreased to 0.7 nm after 91 cycles, and the ALD inhibiting ratio also significantly increased to 92.7%.

(ALD Film Formation Test of Al₂O₃ on SiO₂ Substrate)

ALD film formation test including 45 ALD cycle processes was performed with the same procedures as above, except that a SiO₂ substrate was used instead of the Cu substrate in the ALD film formation test of Al₂O₃ on the Cu substrate. The results are indicated in Table 3.

TABLE 3

| | | | | Al₂O₃ film | |
|---|---|---|---|---|---|
| | Compound | Solvent | Number | thickness | ALD |
| | (P) | (S) | of | on SiO₂ | inhibiting |
| | Type/ | Type/ | ALD | substrate | ratio |
| | mass % | mass % | cycles | (nm) | (%) |
| Example 1 | P1/0.1 | S1/99.9 | 0 | 0.0 | — |
| | | | 18 | 2.0 | 0 |
| | | | 45 | 4.9 | 2 |
| Comparative | P2/0.1 | S1/99.9 | 0 | 0.0 | — |
| Example 1 | | | 18 | 1.9 | 5 |
| | | | 45 | 4.9 | 2 |
| Reference | — | — | 0 | 0.0 | — |
| Comparative | | | 18 | 2.0 | — |
| Example 2 | | | 45 | 5.0 | — |

It can be seen from the results of Reference Comparative Example 2 that in a case in which the ALD film formation was performed without surface treating the SiO₂ substrate with a surface treatment agent, the film thickness of Al₂O₃ after 45 cycles was about 5.0 nm. In a case in which a SiO₂ substrate was surface treated with each of the surface treatment agent of Example 1 and Comparative Example 1, the film thicknesses after 45 cycles were approximately the same as the film thickness of Al₂O₃ of the Reference Comparative Example. From these experimental results, it can be seen that octadecylphosphinic acid does not inhibit ALD film formation on the SiO₂ substrate, similarly to octadecylphosphonic acid.

### Examples 1 to 10 and Comparative Example 2

### (Preparation of Surface Treatment Agent)

The following compound (P) was mixed with each of the following solvents and surface treatment agents of Examples 1 to 10 and Comparative Example 2 were prepared.

As the compound (P), the following P1 was used.
P1: octadecylphosphinic acid
As the solvent, the following S1 to S10, which correspond to the organic solvents (S), and the following S11 were used.
S1: isobutanol (relative dielectric constant: 18.22)
S2: toluene (relative dielectric constant: 2.37)
S3: butyl butyrate (relative dielectric constant: 4.55)
S4: benzotrifluoride (relative dielectric constant: 9.18)
S5: propylene glycol monomethyl ether acetate (relative dielectric constant: 9.40)
S6: 1-octanol (relative dielectric constant: 10.21)
S7: methyl isobutyl carbinol (relative dielectric constant: 10.47)
S8: propylene glycol monomethyl ether (relative dielectric constant: 12.71)
S9: benzyl alcohol (relative dielectric constant: 13.70)
S10: γ-butyrolactone (relative dielectric constant: 42.10)
S11: water (relative dielectric constant: 78.36)
(ALD Film Formation Test of Al₂O₃ on Cu Substrates)

Using the surface treatment agents of Examples 1 to 10 and Comparative Example 2, surface treatment of Cu substrates and ALD film formation test of Al₂O₃ were performed according to the following procedures.

### (Procedures)

1. Pretreatment was carried out by immersing the Cu substrate in a 25 ppm aqueous HF solution for 1 minute at 25° C.
2. The Cu substrate after the pretreatment was washed with deionized water for 1 minute. The Cu substrate after washing with water was dried by a stream of nitrogen.
3. The Cu substrate after drying was immersed in a surface treatment agent for 1 minute, followed by stirring and washing with isopropanol for 1 minute, rinsing with deionized water, and then nitrogen blowing.
4. The ALD cycle process was performed 45 times under the following conditions:
Atomic Layer Deposition (ALD) Equipment: AT-410 (manufactured by Anric Technologies)
Chamber temperature: 150° C.
Precursor: trimethylaluminum and H₂O

After performing the ALD cycle process 45 times, a film thickness of Al₂O₃ on the Cu substrate was measured by fluorescent X-ray analysis. The results are shown in Table 4.

### (Measurement of Water Contact Angle)

In the ALD film formation test, the water contact angles of the Cu substrate after nitrogen blowing of the procedure 3 and the Cu substrate after the ALD cycle process of the procedure 4 were measured. The water contact angle was measured by dropping droplets (2.0 μL) of pure water on the surface of each substrate, using a Dropmaster 700 (manufactured by Kyowa Interface Science Co., Ltd.), and measuring the contact angle as a contact angle at 2 seconds after dropping. The results are given in Table 4.

TABLE 4

| | | | Relative | | | Al₂O₃ film |
|---|---|---|---|---|---|---|
| | Compound | Solvent | dielectric | Water contact angle | | thickness |
| | (P) | (S) | constant | on Cu substrate (°) | | on Cu |
| | Type | Type | of solvent | Before ALD | After ALD | substrate (nm) |
| Example 2 | P1 | S2 | 2.37 | 109.7 | 101.3 | 0.560 |
| Example 3 | P1 | S3 | 4.55 | 109.3 | 107.3 | 0.434 |
| Example 4 | P1 | S4 | 9.18 | 105.2 | 105.3 | 0.635 |
| Example 5 | P1 | S5 | 9.40 | 102.3 | 99.6 | 0.541 |
| Example 6 | P1 | S6 | 10.21 | 101.9 | 105.9 | 0.501 |
| Example 7 | P1 | S7 | 10.47 | 105.1 | 99.1 | 0.660 |
| Example 8 | P1 | S8 | 12.71 | 104.2 | 104.2 | 0.535 |
| Example 9 | P1 | S9 | 13.70 | 107.1 | 108.5 | 0.497 |
| Example 1 | P1 | S1 | 18.22 | 102.8 | 104.6 | 0.577 |
| Example 10 | P1 | S10 | 42.10 | 101.1 | 61.9 | 1.185 |
| Comparative | P1 | S11 | 78.36 | 41.5 | 12.1 | 4.658 |
| Example 2 | | | | | | |
| Reference | — | — | — | 41.3 | 10.0 | 4.978 |
| Comparative | | | | | | |
| Example 3 | | | | | | |

“Reference Comparative Example 3” in Table 4 indicates a test example in which among the procedures 1 to 4 of the ALD film formation, the surface treatment of the procedure 3 was not carried out. It can be seen from the results of Reference Comparative Example 3 that in a case in which the ALD film formation was performed without surface treating the Cu substrate with a surface treatment agent, the film thickness of Al₂O₃ after 45 cycles was about 5.0 nm. In the surface treatment of the Cu substrate with the surface treatment agent of Comparative Example 2, the film thickness of Al₂O₃ was about 4.7 nm and film thickness Al₂O₃ hardly decreased. On the other hand, in the surface treatment with the surface treatment agents of Examples 1 to 10, all the film thickness of Al₂O₃ decreased. It can be seen that in Examples 1 to 10, in a case in which surface treatment was carried out with a surface treatment agent containing an organic solvent having a low relative dielectric constant, an effect that the Al₂O₃ film thickness is decreased increased.

What is claimed is:

1. A surface treatment agent for use in treating a substrate surface,
the surface comprising two or more regions,
the two or more regions comprising at least one metal region and at least one insulator region,
of the two or more regions, the at least one metal region and the at least one insulator region being adjacent to each other, and
the surface treatment agent comprising:
a compound (P) represented by the following general formula (P-1):
HO—P(═O)R¹R² (P-1)
wherein R¹ and R² are each independently bonded to the phosphorus atom and are each independently a hydrogen atom, an alkyl group, a fluorinated alkyl group, or an aromatic hydrocarbon group which may have a substituent, provided that R¹ and R² are not hydrogen atoms at the same time; and
an organic solvent (S).

2. The surface treatment agent according to claim 1, wherein the organic solvent (S) has a relative dielectric constant of 35 or less.

3. The surface treatment agent according to claim 2, wherein the organic solvent (S) has a relative dielectric constant of 20 or less.

4. The surface treatment agent according to claim 1, wherein the metal is at least one type selected from the group consisting of copper, cobalt, aluminum, silver, nickel, titanium, gold, chromium, molybdenum, tungsten, ruthenium, titanium nitride, and tantalum nitride; and the insulator is at least one type selected from the group consisting of aluminum oxide, titanium oxide, zirconium oxide, hafnium oxide, tantalum oxide, silicon oxide, fluorine-containing silicon oxide, carbon-containing silicon oxide, silicon nitride, boron nitride, silicon carbide, silicon carbonitride, silicon oxynitride and silicon oxycarbonitride.

5. A method of threating a surface of a substrate,
the surface comprising two or more regions,
the two or more regions comprising at least one metal region and at least one insulator region,
of the two or more regions, the at least one metal region and the at least one insulator region being adjacent to each other,
the method comprising exposing the surface to the surface treatment agent according to claim 1,
wherein a water contact angle of the metal region is higher than a water contact angle of the insulator region adjacent to the metal region by 10° or more through the reaction between the compound (P) and the regions.

6. A method for region-selectively forming a film on a substrate surface, the method comprising:
treating the surface of the substrate by the surface treatment method according to claim 5; and
forming a film on the surface of the substrate subjected to the surface treatment, by an atomic layer deposition method,
wherein a larger amount of a material for the film is deposited on the insulator region than on the metal region.
